(19) United States
(12) Patent Application Publication
(10) Pub. No.: US 2016/0283319 A1
(43) Pub. Date: Sep. 29, 2016

(54) DATA STORAGE DEVICE AND ENCODING METHOD THEREOF

(71) Applicant: Silicon Motion, Inc., Jhubei City (TW)

(72) Inventor: Po-Sheng Chou, Toufen City (TW)

(21) Appl. No.: 15/074,470

(22) Filed: Mar. 18, 2016

(30) Foreign Application Priority Data
Mar. 27, 2015 (TW) 104109929

(51) Int. Cl. G06F 11/10; G11C 29/52

(52) U.S. Cl. CPC G06F 11/108; G06F 11/1004; G06F 11/1072; G11C 29/52

(57) ABSTRACT

A data storage device including a flash memory and a controller. The flash memory includes a chip, wherein the chip has a plurality of word lines, each of the word lines controls at least one page, and each of the pages includes a predetermined data sector. The controller groups the pages into a plurality of page groups according to the word lines, and encodes the predetermined data sectors of the pages in the same page group into a parity code, wherein any two of the pages in the same page group are controlled by the different word lines.

### CROSS REFERENCE TO RELATED APPLICATIONS

This Application claims priority of Taiwan Patent Application No. 104109929, filed on Mar. 27, 2015, the entirety of which is incorporated by reference herein.

### BACKGROUND OF THE INVENTION

1. Field of the Invention

The present invention relates to an encoding method of a data storage device, and in particular to an encoding method based on the word lines of the data storage device.

2. Description of the Related Art

Flash memory is considered a non-volatile data-storage device, using electrical methods to erase and program itself. NAND Flash, for example, is often used in memory cards, USB flash devices, solid state devices, eMMCs, and other memory devices.

Flash memory such as NAND Flash uses a multiple-block structure to store data. Each block contains multiple pages, wherein the write unit of the flash memory is page, and the erase unit of the flash memory is block. Due to the possibility of errors occurring during the flash memory data storage procedure, the system now encodes the original data then stores the encoded data into flash memory; when data is read, the encoded data is first extracted then decoded back into the original data. Conventional encoding methods are arranged to encode the data according to the sequence of the pages. However, the pages which are adjacent to each other may be damaged at the same time due to their physical characteristics, such that the conventional encoding method cannot correct data in the above situation.

### BRIEF SUMMARY OF THE INVENTION

A detailed description is given in the following embodiments with reference to the accompanying drawings.

An exemplary embodiment provides a data storage device including a flash memory and a controller. The flash memory includes a chip, wherein the chip has a plurality of word lines, each of the word lines controls at least one page, and each of the pages comprises a predetermined data sector. The controller groups the pages into a plurality of page groups according to the word lines, and encodes the predetermined data sectors of the pages in the same page group into a parity code, wherein any two of the pages in the same page group are controlled by the different word lines.

Another exemplary embodiment provides a data storage device including a flash memory and a controller. The flash memory includes a chip, wherein the chip has a plurality of word lines, each of the word lines controls a plurality of pages, and each of the pages has a predetermined data sector. The controller reads the pages in a page group, encodes the predetermined data sectors of the read pages in the page group into a parity code, and writes the parity code into the flash memory, wherein the pages controlled by the same word line are assigned to the different page groups.

Another exemplary embodiment provides an encoding method applied to a data storage device having a flash memory. The flash memory includes a chip, the chip has a plurality of word lines, each of the word lines controls at least one page, and each of the pages has a predetermined data sector. The encoding method includes: grouping the pages into a plurality of page groups according to the word lines; and encoding the predetermined data sectors of the pages in the same page group into a parity code, wherein any two of the pages in the same page group are controlled by the different word lines.

Another exemplary embodiment further provides an encoding method applied to a data storage device having a flash memory, wherein the flash memory comprises a chip, the chip has a plurality of word lines, each of the word lines controls at least one page, each of the pages has a predetermined data sector. The encoding method includes: reading the pages in a page group: encoding the predetermined data sectors of the read pages in the page group into a parity code; and writing the parity code into the flash memory, wherein the pages controlled by the same word line are assigned to the different page groups.

### BRIEF DESCRIPTION OF THE DRAWINGS

The present invention can be more fully understood by reading the subsequent detailed description and examples with references made to the accompanying drawings, wherein:

FIG. 1 is a schematic diagram illustrating an electronic system, constructed in accordance with some embodiments.

FIG. 2 is a schematic diagram illustrating a chip, constructed in accordance with some embodiments.

FIG. 3 is a schematic diagram illustrating another chip, constructed in accordance with some embodiments.

FIG. 4 is a schematic diagram illustrating another chip, constructed in accordance with some embodiments.

FIG. 5 is a schematic diagram illustrating a chip of FIG. 4, constructed in accordance with some embodiments.

FIG. 6 is a schematic diagram illustrating another chip, constructed in accordance with some embodiments.

FIG. 7 is a flowchart of an encoding method constructed in accordance with some embodiments.

FIG. 8 is a flowchart of another encoding method constructed in accordance with some embodiments.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

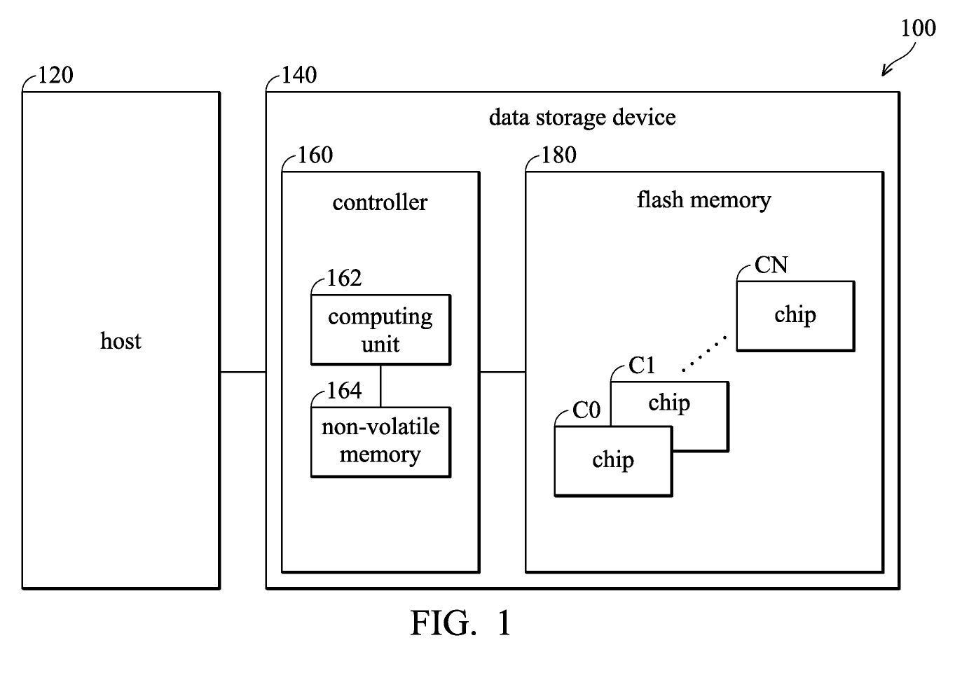

FIG. 1 is a schematic diagram illustrating an electronic system, constructed in accordance with some embodiments. The electronic system 100 includes a host 120 and a data storage device 140. The data storage device 140 includes a flash memory 180 and a controller 160, and operates in response to the commands of the host 110.

The controller 160 includes a computing unit 162 and a non-volatile memory 164 (ROM). The non-volatile memory 164, the program code stored in the non-volatile memory 164 and data stored in the non-volatile memory 164 constitute firmware executed by the processing unit 162, and the controller 160 is configured to control the flash memory 180 based on the firmware. Moreover, the computing unit 162 may further include an error correction engine (not shown). The error correction engine is arranged to perform error correction (ECC) on the retrieved data to correct the retrieved data when the retrieved data is wrong, but it is not limited thereto. It should be noted that, in one of the embodiments, the non-volatile memory 164 includes software or firmware arranged to enable the computing unit 162 to encode the predetermined data sectors stored in the pages into predetermined parity code(s).

The flash memory 180 includes a plurality of chips C1-CN, each of the chips C1-CN includes a plurality of pages, a plurality of word lines and a plurality of bit lines, wherein the word lines are arranged in successive sequence, the bit lines are also arranged in successive sequence, and each of the word lines controls at least one page to select the target page. For example, when the flash memory 180 operates as the Single-Level Cell (SLC), each of the word lines is arranged to control one page. When the flash memory 180 operates as the Multi-Level Cell (MLC, each of the word lines is arranged to control two pages (LSB page and MSB page). When the flash memory 180 operates as the Triple-Level Cell (TLC), each of the word lines is arranged to control three pages (LSB page, CSB page, and MSB page), but it is not limited thereto. It should be noted that each of the pages in the chips C1-CN includes a user data and a predetermined data sector, wherein the user data is the content written by the host 120 or the controller 160, and the predetermined data sectors are the metadata of the corresponding pages. The metadata is arranged to record the information of the corresponding page. More specifically, the metadata may include the index, the status, the error correction code (parity code) of the corresponding page, but it is not limited thereto. In other embodiments, the predetermined data sector may also be the content stored in the entire page or the content written by the host 120 or the controller 160.

Due to the physical characteristics of the flash memory, the other pages controlled by the same word line having a damaged page also have a very high possibility to be damaged as well, and the pages controlled by the word line adjacent to another word line which has damaged page(s) also have a very high probability to be damaged as well. The error bits of the damaged pages can be corrected by the parity check using parity code. However, the error correction ability of the parity check is limited. When the number of error bits is greater than a threshold, the parity check cannot successfully correct the data. Therefore, in one of the embodiments, the controller 160 groups the pages into a plurality of page groups G0˜GX based on the word lines, and encodes the predetermined data sectors in the same page group into a parity code. Therefore, the number of page groups G0˜GX and the number of parity codes of the flash memory 180 are the same.

It should be noted that, in one of the embodiments, the controller 160 is configured to assign the pages controlled by the different pages in the same page group. Namely, the controller 160 is configured to assign the pages controlled by the same word line to different page groups. Namely, any two of the pages in the same page group are controlled by different word lines, such that the controller 160 can use different parity codes to correct the pages controlled by a specific word line when all of the pages controlled by the specific word line are damaged.

In another embodiment, the controller 160 is further configured to define the pages controlled by different word lines having an interval of a first predetermined number of word lines in the same group. Namely, any two of the pages in the same page group G0˜GX are respectively controlled by two different word lines which have an interval of a first predetermined number of word lines. For example, the first predetermined number of word lines can be 2, 3, 4, 5, 6, 7, 8, 9, 10, 11 or 12, but it is not limited thereto. Developers may define the first predetermined number of word lines according to the physical characteristics of the different flash memories. In one of the embodiments, two to three word lines which are adjacent to each other in the flash memory 180 are easily damaged at the same time, such that the first predetermined number of word lines can be 3 or 7, but it is not limited thereto. Because of any two of the pages in the same page group G0˜GX are controlled by the different word lines having an interval of a first predetermined number of word lines, the controller 160 can still correct the damaged data by different parity codes encoded with other pages controlled by other word lines when the adjacent word lines are damaged. In the process of producing the parity code, the controller 160 retrieves the predetermined data sectors of the pages in one page group, encodes the retrieved predetermined data sectors of the pages in the page group into a parity code, and writes the parity code into the flash memory 180. For example, when the controller 160 is in the process of producing the parity code of the page group G0, the controller 160 retrieves the pages in the page group G0, encodes the predetermined data sectors of the pages in the page group G0 into a parity code, and writes the parity code into the flash memory 180, and so on. When the controller 160 fails to read the pages by error correction using the metadata, the controller 160 can use the corresponding parity code(s) to correct the error bits.

It should be noted that the encoding calculations are performed by a hardware circuit due to the complication of the calculations. The length of the user data and the metadata of the page are different, such that the computing unit 162 needs to have two different hardware circuits when both of the user data and the metadata need to be protected by the parity code. In one embodiments of the present invention, the controller 160 is configured to perform an exclusive-or operation by a software code stored in a non-volatile memory 164 to encode the predetermined data sectors of the page groups G0˜GX into the parity codes, wherein the predetermined data sector is the metadata of the pages, and the length of the metadata is less than the user data. Namely, the computing unit 162 can only include one hardware circuit to encode the user data of the pages into parity codes, and encode the metadata of the pages by the software.

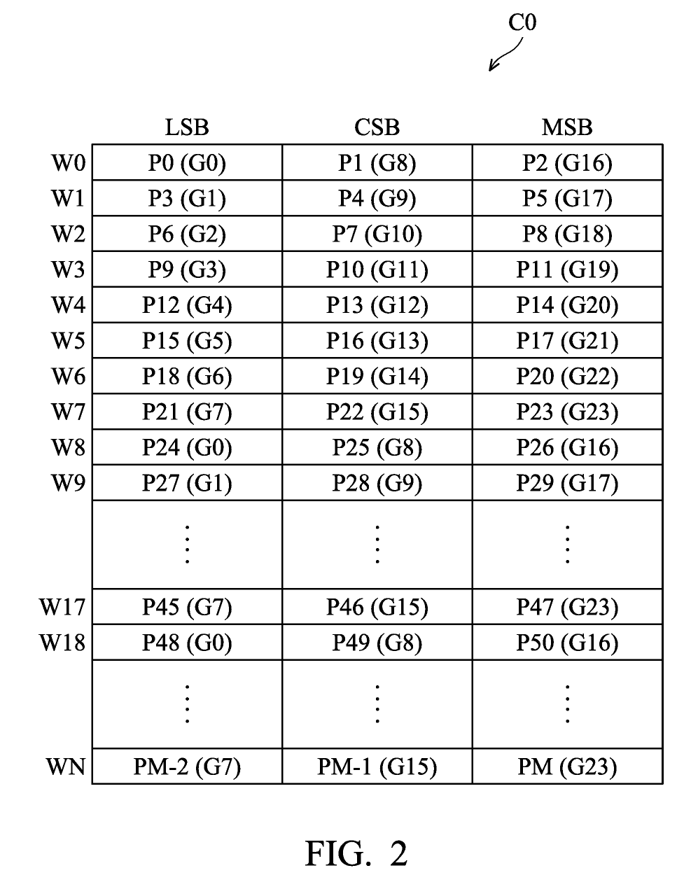

FIG. 2 is a schematic diagram illustrating a chip, constructed in accordance with some embodiments. FIG. 2 is based on chip C0 of the flash memory 180 as an example, but it is not limited thereto. The constructions of the chips C1˜CN is the same as the chip C0. In this embodiment, the chip C0 is operated as the Triple-Level Cells (TLC), wherein each of the word lines controls three pages (LSB page, CSB page, and MSB page). The chip C0 has a plurality of word lines W0˜WN and a plurality of pages P0˜PM. The controller 160 assigns the pages controlled by the word lines which have intervals of a first predetermined number of word lines with each other in the same page group, wherein the first predetermined number of word lines is 7 in this embodiment, but it is not limited thereto. Namely, any two of the pages in the same page group G0˜GX are controlled by two of different word lines which have seven word lines between the two different word lines. In other words, the three pages controlled by the same word line are assigned to different there page groups, respectively.

As shown in FIG. 2, the page P0, the page P1 and the page P2 are controlled by the word line W0, the page P3, the page P4 and the page P5 are controlled by the word line W1, the page P6, the page P7 and the page P8 are controlled by the word line W2, and so on. The controller 160 is configured to assign the LSB pages P0, P3, P6, P9, P12, P15, P18 and P21 controlled by the word lines W0˜W7 respectively to the page groups G0˜G7 in sequence; assign the CSB pages P1, P4, P7, P10, P13, P16, P19 and P22 controlled by the word lines W0˜W7 respectively to the page groups G8˜G15 in sequence; and assign the MSB pages P2, P5, P8, P11, P14, P17, P20 and P23 controlled by the word lines W0˜W7 respectively to the page groups G16˜G23 in sequence. Next, the controller 160 assigns the LSB pages P24, P27, P30, P33, P36, P39, P42, P45 controlled by the word lines W8˜W17, which respectively have intervals of seven word lines between the word lines W0˜W7, to the page groups G0˜G7 in sequence; assigns the CSB pages P25, P28, P31, P34, P37, P40, P43, P46 controlled by the word lines W8˜W17, which respectively have intervals of 7 word lines between the word lines W0˜W7, respectively to the page groups G8˜G15; and assigns the MSB pages P26, P29, P32, P35, P38, P41, P44 and P47 controlled by the word lines W8˜W17, which respectively have intervals of 7 word lines between the word lines W0˜W7, respectively to the page groups G16˜G23, and so on. Therefore, each two of the pages in the same page group G0˜GX are controlled by the word lines which have an interval of at least 7 word lines between each other, but it is not limited thereto.

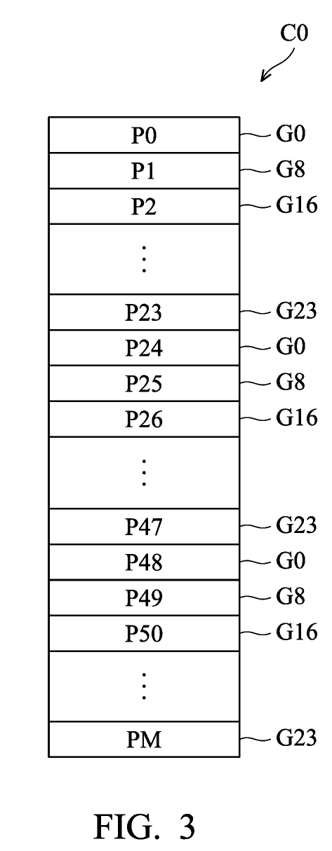

FIG. 3 is a schematic diagram illustrating another chip, constructed in accordance with some embodiments. In FIG. 3, the pages P0˜PM of the chip C0 is arranged in successive sequence. As per the description above based on FIG. 2, any two of the pages in the same page group of the chip have an interval of a second predetermined number of pages, wherein the chip C0 is operated as the Triple-Level Cell (TLC) and the first predetermined number of word lines is 7, such that the second predetermined number is 21, but it is not limited thereto. the second predetermined number of pages corresponds to the first predetermined number of word lines and operation type of the flash memory 180. For example, when the first predetermined number of word lines is 3 and the flash memory 180 is operated as the Triple-Level Cell (TLC), the second predetermined number of pages is 11. As shown in FIG. 3, the page group G0 sequentially includes the pages P0, P24, P48 and P72, etc., which have intervals of 21 pages to each other, and so on. The page group G1 has the pages P3, P27, P51, P75 and so on, wherein the pages in the page group G1 have intervals of 21 pages between each other. The page group G2 has the pages P6, P30, P54, P78 and so on, wherein the pages in the page group G2 have intervals of 21 pages between each other. Similarly, each of the page groups G3˜G23 has pages have intervals of 21 pages between each other.

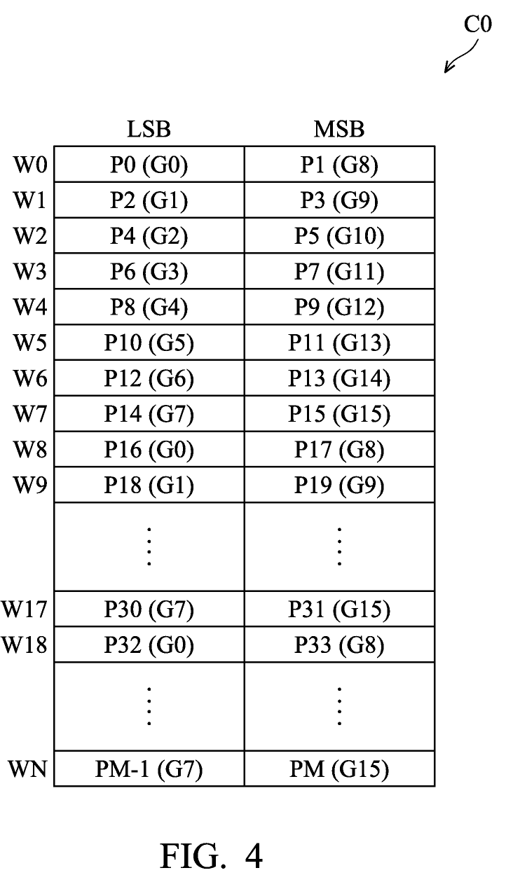

FIG. 4 is a schematic diagram illustrating another chip, constructed in accordance with some embodiments. FIG. 4 is based on chip C0 of the flash memory 180 as an example, but it is not limited thereto. The constructions of the chips C1˜CN are the same as the chip C0. In this embodiment, the chip C0 is operated as the Multi-Level Cell (MLC), wherein each of the word lines controls two pages (LSB page and MSB page). The chip C0 has a plurality of word lines W0˜WN and a plurality of pages P0˜PM. The controller 160 assigns the pages controlled by the word lines which have intervals of a first predetermined number of word lines with each other in the same page group, wherein the first predetermined number of word lines is 7 in this embodiment, but it is not limited thereto. Namely, any two of the pages in the same page group G0˜GX are controlled by two of different word lines which have seven word lines between the two different word lines. In other words, the two pages controlled by the same word line are assigned to different there page groups, respectively.

As shown in FIG. 4, the page P0 and the page P1 are controlled by the word line W0, the page P2 and the page P3 are controlled by the word line W1, the page P4 and the page P5 are controlled by the word line W2, and so on. The controller 160 is configured to assign the LSB pages P0, P2, P4, P6, P8, P10, P12 and P14 controlled by the word lines W0˜W7 respectively to the page groups G0˜G7 in sequence; and assign the MSB pages P1, P3, P5, P7, P9, P11, P13 and P15 controlled by the word lines W0˜W7 respectively to the page groups G8˜G15 in sequence. Next, the controller 160 assigns the LSB pages P16, P18, P20, P22, P24, P26, P28 and P30 controlled by the word lines W8˜W17, which respectively have intervals of seven word lines between the word lines W0˜W7, to the page groups G0˜G7 in sequence; assigns the MSB pages P17, P19, P21, P23, P25, P27, P29 and P31 controlled by the word lines W8˜W17, which respectively have intervals of 7 word lines between the word lines W0˜W7, respectively to the page groups G8˜G15, and so on. Therefore, each two of the pages in the same page group G0˜GX are controlled by the word lines which have an interval of at least 7 word lines between each other, but it is not limited thereto.

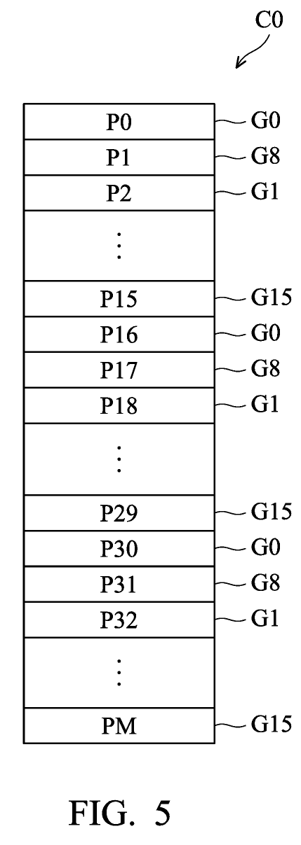

FIG. 5 is a schematic diagram illustrating a chip of FIG. 4, constructed in accordance with some embodiments. In FIG. 5, the pages P0˜PM of the chip C0 is arranged in successive sequence. As in the description related to FIG. 4 above, any two of the pages in the same page group G0˜GX have an interval of a second predetermined number of pages, wherein the chip C0 is the Multi-Level Cell (MLC) and the first predetermined number is 7, such that the second predetermined number is 15. As shown in FIG. 5, the page group G0 includes the pages P0, P16, P32, P48 which have an interval of 15 pages, and so on. The page group G1 includes the pages P2, P18, P34, P50 which have an interval of 15 pages, and so on. The page group G2 includes the pages P4, P20, P36, P52 which have an interval of 15 pages, and so on. Similarly, the pages of the page group G3˜G15 are also have an interval of 15 pages.

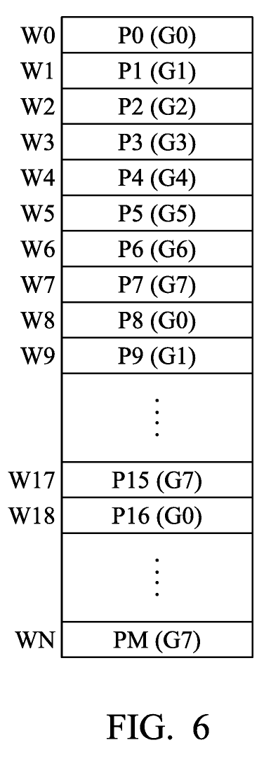

FIG. 6 is a schematic diagram illustrating another chip, constructed in accordance with some embodiments. FIG. 6 is based on chip C0 of the flash memory 180 as an example, but it is not limited thereto. The constructions of the chips C1˜CN is the same as the chip C0. In this embodiment, the chip C0 is operated as the Single-Level Cell (SLC), wherein each of the word lines controls one page. The chip C0 has a plurality of word lines W0˜WN and a plurality of pages P0˜PM. The controller 160 assigns the pages controlled by the word lines which have intervals of a first predetermined number of word lines with each other in the same page group, wherein the first predetermined number of word lines is 7 in this embodiment, but it is not limited thereto. Namely, any two of the pages in the same page group G0˜GX are controlled by two of different word lines which have seven word lines between the two different word lines.

As shown in FIG. 6, the page P0 is controlled by the word line W0, the page P1 is controlled by the word line W1, the page P2 is controlled by the word line W2, and so on. The controller 160 is configured to assign the LSB pages P0˜P7 controlled by the word lines W0˜W7 respectively to the page groups G0˜G7 in sequence. Next, the controller 160 assigns the LSB pages P8˜P15 controlled by the word lines W8˜W17, which respectively have intervals of seven word lines between the word lines W0˜W7, to the page groups G0˜G7 in sequence, and so on. Therefore, each two of the pages in the same page group G0˜GX are controlled by the word lines which have an interval of at least 7 word lines between each other, but it is not limited thereto.

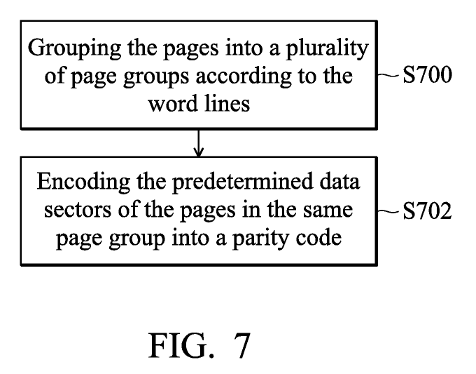

FIG. 7 is a flowchart of an encoding method constructed in accordance with some embodiments. The encoding method is applied to the data storage device 140 of FIG. 1. The process starts at step S700.

In step S700, the controller 160 groups the pages into a plurality of page groups G0˜GX according to the word lines. In one of the embodiments, the controller 160 defines the pages controlled by different word lines in the same page group. Namely, any two of the pages in the same page groups G0˜GX in controlled by the different word lines. In another embodiment, the controller 160 is further configured to assign the pages which are control by different word lines, which have intervals of a first predetermined number of word lines between each other, to the same page group. Namely, any two of the pages in the same page group G0˜GX are respectively controlled by two different word lines which have an interval of a first predetermined number of word lines. For example, the first predetermined number of word lines can be 2, 3, 4, 5, 6, 7, 8, 9, 10, 11 or 12, but it is not limited thereto. Developers may define the first predetermined number of word lines according to the physical characteristics of the different flash memories. In one of the embodiments, two to three word lines which are adjacent to each other in the flash memory 180 are easily damaged at the same time, such that the first predetermined number of word lines can be 3 or 7, but it is not limited thereto. The details of how to define the page groups G0˜GX can be referred to FIG. 2-6.

Next, in step S702, the controller 160 encodes the predetermined data sectors of the pages in the same page group G0˜GX into a parity code. In one embodiment, any two of the pages in the same page group G0˜GX are controlled by the different word lines, such that the controller 160 can still correct the damaged data, which is stored in the pages controlled by a specific word line, by different parity codes encoded with other pages controlled by other word lines when all of the pages controlled by the specific word line are damaged. In another embodiment, any two of the pages in the same page group G0˜GX are controlled by the different word lines having an interval of a first predetermined number of word lines, such that the controller 160 can still correct the damaged data by different parity codes encoded with other pages controlled by other word lines when the adjacent word lines are damaged. The process ends at step S702.

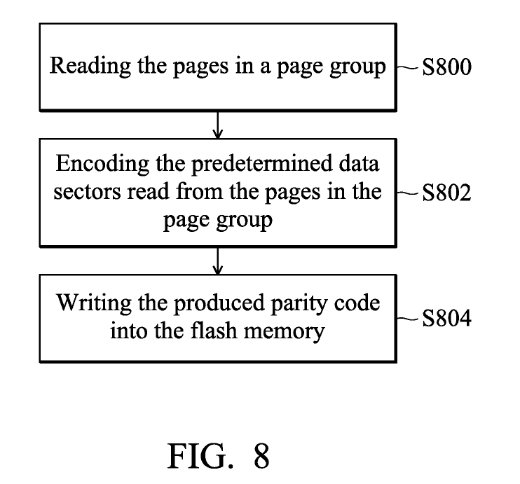

FIG. 8 is a flowchart of another encoding method constructed in accordance with some embodiments. The encoding method is applied to the data storage device 140 of FIG. 1. The process starts at step S800.

In step S800, the controller 160 reads the pages in a page group.

Next, in step S802, the controller 160 encodes the predetermined data sectors read from the pages in the page group in the step S800 into a parity code.

Next, in step S804, the controller 160 writes the produced parity code into the flash memory 140. Next, the controller 160 repeats the steps S800˜S804 until all of the predetermined data sectors of the pages in the chip are encoded into parity codes. For example, when the controller 160 is in the process of producing the parity code of the page group G0, the controller 160 retrieves the pages in the page group G0, encodes the predetermined data sectors of the pages in the page group G0 into a parity code, and writes the parity code into the flash memory 180, and so on. When the controller 160 fails to read the pages by error correction using the metadata, the controller 160 can use the corresponding parity code(s) to correct the error bits.

The data storage device and the encoding method of the various embodiments can group the pages into a plurality of page groups based on the word lines to encode the predetermined data sectors stored in the pages into parity codes by page groups. Moreover, the data storage device and the encoding method of the various embodiments can also correct the error bits of the pages controlled by the same word line by different parity codes encoded by the data of the pages controlled by other word lines when the pages controlled by the same word line are damaged. Furthermore, the data storage device and the encoding method of the various embodiments can also correct the error bits of the pages controlled by the adjacent word lines by different parity codes encoded by the data of the pages controlled by other word lines when the pages controlled by the adjacent word lines are damaged.

Data transmission methods, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising:
a flash memory, comprising a chip, wherein the chip has a plurality of word lines, each of the word lines controls at least one page, and each of the pages comprises a predetermined data sector; and
a controller, grouping the pages into a plurality of page groups according to the word lines, and encoding the predetermined data sectors of the pages in the same page group into a parity code, wherein any two of the pages in the same page group are controlled by the different word lines.

2. The data storage device as claimed in claim 1, wherein the word lines of the chip are arranged in sequence and adjacent to each other in the sequence, and any two of the pages which are in the same page group and adjacent to each other are respectively controlled by two of the different word lines having an interval of a first predetermined number of word lines.

3. The data storage device as claimed in claim 2, wherein the first predetermined number of word lines is 3 or 7.

4. The data storage device as claimed in claim 1, wherein the pages of the chip are arranged in sequence, and any two of the pages which are in the same page group and adjacent to each other have an interval of a second predetermined number of pages.

5. The data storage device as claimed in claim 4, wherein the second predetermined number of pages is 11 or 23.

6. The data storage device as claimed in claim 1, wherein the predetermined data sectors are metadata of the corresponding pages, and the controller performs an exclusive-or operation by a software code to encode the predetermined data sectors in the same page group into the parity code.

7. A data storage device, comprising:
a flash memory, comprising a chip, wherein the chip has a plurality of word lines, each of the word lines controls a plurality of pages, and each of the pages has a predetermined data sector; and
a controller, reading the pages in a page group, encoding the predetermined data sectors of the read pages in the page group into a parity code, and writing the parity code into the flash memory, wherein the pages controlled by the same word line are assigned to the different page groups.

8. The data storage device as claimed in claim 7, wherein the word lines of the chip are arranged in successive sequence, and any two of the pages which are in the same page group and adjacent to each other are respectively controlled by two of the different word lines having an interval of a first predetermined number of word lines.

9. The data storage device as claimed in claim 7, wherein the pages of the chip are arranged in successive sequence, and any two of the pages which are in the same page group and adjacent to each other have an interval of a second predetermined number of pages.

10. The data storage device as claimed in claim 7, wherein the predetermined data sectors are metadata of the corresponding pages, and the controller performs an exclusive-or operation by a software code to encode the predetermined data sectors in the same page group into the parity code.

11. An encoding method, applied to a data storage device having a flash memory, wherein the flash memory comprises a chip, the chip has a plurality of word lines, each of the word lines controls at least one page, each of the pages has a predetermined data sector, and the encoding method comprises:
grouping the pages into a plurality of page groups according to the word lines; and
encoding the predetermined data sectors of the pages in the same page group into a parity code, wherein any two of the pages in the same page group are controlled by the different word lines.

12. The encoding method as claimed in claim 11, wherein the word lines of the chip are arranged in successive sequence, and any two of the pages which are in the same page group and adjacent to each other are respectively controlled by two of the different word lines having an interval of a first predetermined number of word lines.

13. The encoding method as claimed in claim 12, wherein the first predetermined number of word lines is 3 or 7.

14. The encoding method as claimed in claim 11, wherein the pages of the chip are arranged in sequence, and any two of the pages which are in the same page group and adjacent to each other have an interval of a second predetermined number of pages.

15. The encoding method as claimed in claim 14, wherein the second predetermined number of pages is 11 or 23.

16. The encoding method as claimed in claim 11, wherein the predetermined data sectors are metadata of the corresponding pages, and the step of encoding the predetermined data sectors of the pages in the same page group into the parity code comprises performing an exclusive-or operation by a software code to encode the predetermined data sectors in the same page group into the parity code.

17. An encoding method, applied to a data storage device having a flash memory, wherein the flash memory comprises a chip, the chip has a plurality of word lines, each of the word lines controls at least one page, each of the pages has a predetermined data sector, and the encoding method comprises:
reading the pages in a page group:
encoding the predetermined data sectors of the read pages in the page group into a parity code; and
writing the parity code into the flash memory, wherein the pages controlled by the same word line are assigned to the different page groups.

18. The encoding method as claimed in claim 17, wherein the word lines of the chip are arranged in sequence and adjacent to each other in the sequence, and any two of the pages which are in the same page group and adjacent to each other are respectively controlled by two of the different word lines having an interval of a first predetermined number of word lines.

19. The encoding method as claimed in claim 17, wherein the pages of the chip are arranged in sequence, and any two of the pages which are in the same page group and adjacent to each other have an interval of a second predetermined number of pages.

20. The encoding method as claimed in claim 17, wherein the predetermined data sectors are metadata of the corresponding pages, and the controller performs an exclusive-or operation by a software code to encode the predetermined data sectors in the same page group into the parity code.
